(19) United States
(12) Patent Application Publication
(10) Pub. No.: US 2004/0239372 A1
(43) Pub. Date: Dec. 2, 2004

(54) RF differential signal squarer/limiter and balancer with high power supply rejection

(76) Inventors: Chih-Ming Hung, McKinney, TX (US); Chien-Chung Chen, Plano, TX (US); Dirk Leipold, Plano, TX (US)

Correspondence Address: TEXAS INSTRUMENTS INCORPORATED, P O BOX 655474, M/S 3999, DALLAS, TX, 75265

(21) Appl. No.: 10/448,712

(22) Filed: May 30, 2003

(51) Int. Cl. H03K 5/22

(52) U.S. Cl. 327/65

(57) ABSTRACT

The differential signal squarer/limiter and balancer circuit includes: a complementary differential pair MP5, MP6, MN2, and MN3; and a complementary positive feedback amp MP11, MP12, MN12, and MN13 coupled to the complementary differential pair.

### FIELD OF THE INVENTION

This invention generally relates to electronic systems and in particular it relates to differential signal squarer/limiter circuits.

### BACKGROUND OF THE INVENTION

Conventionally, it is common that a differential amplifier is used to convert a sine-wave differential signal to a square-wave differential signal. However, this can be done only for a low frequency (less than a few hundred MHz) if the power consumption of the amplifier is limited. Furthermore, the duty cycle is typically not well controlled and the phase noise performance is commonly not good in the conventional implementation due to the fact that a lot of transistors are constantly “ON” contributing noise.

### SUMMARY OF THE INVENTION

A differential signal squarer/limiter and balancer circuit includes: a complementary differential pair; and a complementary positive feedback amp coupled to the complementary differential pair.

### BRIEF DESCRIPTION OF THE DRAWINGS

In the drawings:

The drawing is a schematic diagram of a preferred embodiment differential signal squarer/limiter circuit.

### DETAILED DESCRIPTION OF PREFERRED EMBODIMENTS

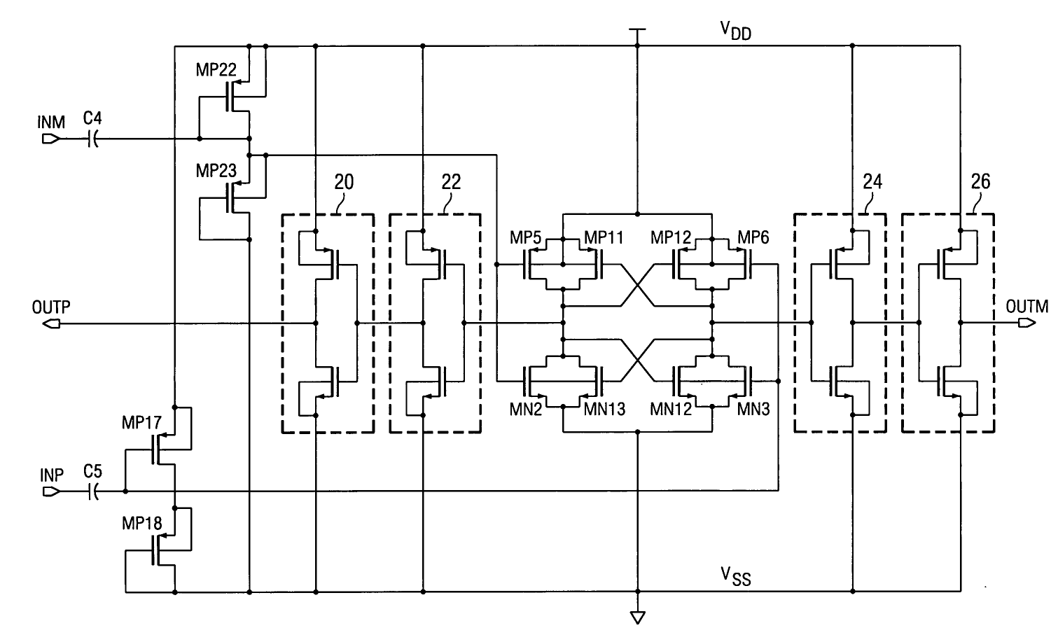

The preferred embodiment circuit shown in the Drawing solves the problem of implementing a low-power low-phase-noise sine-to-square-wave converter at RF (GHz) frequency with low even harmonics and high power supply rejection. Other solutions typically use operational amplifier based topology. The preferred embodiment solution does not use an operational amplifier. It uses a complementary differential pair and a latch. The circuit of FIG. 1 includes PMOS transistors MP5, MP6, MP11, MP12, MP17, MP18, MP22, and MP23; NMOS transistors MN2, MN3, MN12, and MN13; inverters 20, 22, 24, and 26; capacitors C4 and C5; inputs INM and INP; outputs OUTM and OUTP; and source voltages VDD and VSS. This circuit can further be used to balance a differential square-wave clock signal resulting in an enhanced precision of zero crossing when power supply varies.

Transistors MN2, MN3, MP5, and MP6 form complementary differential pairs to amplify the input sine-wave signal. Transistors MP11, MP12, MN12, and MN13 form a complementary positive-feedback amplifier to bring the internal signal voltage swing to rail-to-rail. Two inverters (buffers) on each side (inverters 20, 22, 24, and 26) further buffer the output differential square signal for the next stage circuits. Capacitors C4 and C5, and transistors MP17, MP18, MP22, and MP23 form an AC coupling and DC biasing for the complementary differential pair. This circuit can be configured to consume less than 0.5 mA with a broad-band phase noise floor of ˜−155 dBc/Hz. The noise floor can be pushed lower if the current consumption is increased.

The preferred embodiment solution provides several advantages. The circuit is able to convert a sine-wave RF signal to a square-wave RF signal. The circuit has low power consumption. The circuit has low even harmonics at the output. The circuit has high power supply rejection. The variation of zero crossing is reduced when the power supply varies, resulting in a higher RF clock precision and lower spur level in frequency spectrum.

While this invention has been described with reference to an illustrative embodiment, this description is not intended to be construed in a limiting sense. Various modifications and combinations of the illustrative embodiment, as well as other embodiments of the invention, will be apparent to persons skilled in the art upon reference to the description. It is therefore intended that the appended claims encompass any such modifications or embodiments.

1. A differential signal squarer/limiter and balancer circuit comprising:
a complementary differential pair; and
a complementary positive feedback amp coupled to the complementary differential pair.

2. A differential signal squarer/limiter and balancer circuit comprising:
a first transistor;
a second transistor coupled in series with the first transistor, wherein the first and second transistors form a first branch of a complementary differential pair;
a third transistor;
a fourth transistor coupled in series with the third transistor, wherein the third and fourth transistors form a second branch of the complementary differential pairs
a fifth transistor coupled in parallel with the first transistor, and having a control node coupled to a node between the third and fourth transistors;
a sixth transistor coupled in parallel with the second transistor, and having a control node coupled to the node between the third and fourth transistors;
a seventh transistor coupled in parallel with the third transistor, and having a control node coupled to a node between the first and second transistors; and
an eighth transistor coupled in parallel with the fourth transistor, and having a control node coupled to the node between the first and second transistors.

3. The circuit of claim 2 wherein the first and third transistors are P-type transistors, and the second and fourth transistors are N-type transistors.

4. The circuit of claim 1 wherein the complementary positive amp comprises:
a first transistor;
a second transistor coupled in series with the first transistor;
a third transistor;
a fourth transistor coupled in series with the third transistor, wherein a control node of the first transistor and a control node of the second transistor are coupled to a node between the third and fourth transistors, and a control node of the third transistor and a control node of the fourth transistor are coupled to a node between the first and second transistors.

5. The circuit of claim 4 wherein the first and third transistors are P-type transistors, and the second and fourth transistors are N-type transistors.

6. The circuit of claim 2 wherein the complementary positive amp comprises:
a fifth transistor coupled in parallel with the first transistor, and having a control node coupled to a node between the third and fourth transistors;
a sixth transistor coupled in parallel with the second transistor, and having a control node coupled to the node between the third and fourth transistors;
a seventh transistor coupled in parallel with the third transistor, and having a control node coupled to a node between the first and second transistors;
an eighth transistor coupled in parallel with the fourth transistor, and having a control node coupled to the node between the first and second transistors.

7. The circuit of claim 2 wherein the first, third, fifth, and seventh transistors are P-type transistors, and the second, fourth, sixth, and eighth transistors are N-type transistors.

8. The circuit of claim 2 further comprising:
a first buffer coupled to a first output of the complementary differential pair; and
a second buffer coupled to a second output of the complementary differential pair.

9. The circuit of claim 8 wherein the first buffer comprises two inverters coupled in series, and the second buffer comprises two inverters coupled in series.

10. The circuit of claim 2 further comprising: a DC biasing circuit for the complementary differential pair.

11. The circuit of claim 2 further comprising an AC coupling circuit coupled to an input of the complementary differential pair.

12. A circuit comprising:
a first transistor;
a second transistor coupled in series with the first transistor, wherein the first and second transistors form a first branch of a complementary differential pair;
a third transistor;
a fourth transistor coupled in series with the third transistor, wherein the third and fourth transistors form a second branch of the complementary differential pair;
a fifth transistor coupled in parallel with the first transistor, and having a control node coupled to a node between the third and fourth transistors;
a sixth transistor coupled in parallel with the second transistor, and having a control node coupled to the node between the third and fourth transistors;
a seventh transistor coupled in parallel with the third transistor, and having a control node coupled to a node between the first and second transistors;
an eighth transistor coupled in parallel with the fourth transistor, and having a control node coupled to the node between the first and second transistors;
a first buffer circuit coupled to a first output of the complementary differential pair;
a second buffer circuit coupled to a second output of the complementary differential pair;
a first DC biasing circuit coupled to a first input of the complementary differential pair; and
a second DC biasing circuit coupled to a second input of the complementary differential pair.

13. The circuit of claim 12 further comprising:
a first AC coupling circuit coupled to the first input of the complementary differential pair; and
a second AC coupling circuit coupled to the second input of the complementary differential pair.

14. The circuit of claim 12 wherein the complementary differential pair comprises:
a first transistor;
a second transistor coupled in series with the first transistor, wherein the first and second transistors form a first branch of the complementary differential pair;
a third transistor; and
a fourth transistor coupled in series with the third transistor, wherein the third and fourth transistors form a second branch of the complementary differential pair.

15. The circuit of claim 14 wherein the first and third transistors are P-type transistors, and the second and fourth transistors are N-type transistors.

16. The circuit of claim 12 wherein the complementary positive amp comprises:
a first transistor;
a second transistor coupled in series with the first transistor;
a third transistor;
a fourth transistor coupled in series with the third transistor, wherein a control node of the first transistor and a control node of the second transistor are coupled to a node between the third and fourth transistors, and a control node of the third transistor and a control node of the fourth transistor are coupled to a node between the first and second transistors.

17. The circuit of claim 16 wherein the first and third transistors are P-type transistors, and the second and fourth transistors are N-type transistors.

18. The circuit of claim 14 wherein the complementary positive amp comprises:
a fifth transistor coupled in parallel with the first transistor, and having a control node coupled to a node between the third and fourth transistors;
a sixth transistor coupled in parallel with the second transistor, and having a control node coupled to the node between the third and fourth transistors;
a seventh transistor coupled in parallel with the third transistor, and having a control node coupled to a node between the first and second transistors;
an eighth transistor coupled in parallel with the fourth transistor, and having a control node coupled to the node between the first and second transistors.

19. The circuit of claim 12 wherein the first, third, fifth, and seventh transistors are P-type transistors, and the second, fourth, sixth, and eighth transistors are N-type transistors.
